(19) United States
(12) Patent Application Publication
(10) Pub. No.: US 2008/0298456 A1
(43) Pub. Date: Dec. 4, 2008

(54) Hybrid Digital Digital/Analog Fm Multiplexer Transmitter

(75) Inventors: John R. Haggis, San Jose, CA (US); John Glissman, Metro Manila (PH); Arthur L. Cohen, Cupertino, CA (US)

Correspondence Address: STAINBROOK & STAINBROOK, LLP, 412 AVIATION BOULEVARD, SUITE H, SANTA ROSA, CA, 95403, US

(73) Assignee: AERIELLE TECHNOLOGIES, INC., Mountain View, CA (US)

(21) Appl. No.: 12/095,903

(22) PCT Filed: Dec. 2, 2006
(86) PCT No.: PCT/US2006/061537

§ 371 Date: Jun. 2, 2008

Related U.S. Application Data
(60) Provisional application No. 60/742,019, filed on Dec. 2, 2005.

(51) Int. Cl. H03K 7/08

(52) U.S. Cl. 375/238; 375/295

(57) ABSTRACT

An audio circuit digitizes raw analog input and uses a digital signal processor (DSP) to filter, modulate, and mix the input to produce a multiplex composite signal. The multiplex composite signal is output from the DSP through a digital/analog converter (DAC), and modulates a conventional FM RF stage. In a first preferred, hydrid embodiment, the composite signal is output from the DSP through a digital/analog converter (DAC), and modulates a conventional FM RF stage. In a second preferred, fully digital embodiment, carrier modulation takes place in the DSP, and FM modulated RF is output via a fast DAC for final filtering and radiation.

### BACKGROUND OF THE INVENTION

1. Technical Field

The present invention relates generally to portable consumer electronic devices, and more particularly to digital FM transmitters, and still more particularly to a hybrid digital/analog FM multiplexer/transmitter.

### BACKGROUND ART

The analog FM transmitter market is becoming increasingly saturated, with little room for improvement, advancement, or differentiation. However, there is ample room for radically new approaches to FM transmitter technology. While studio digital FM transmitters exist, no consumer chipset is available which is sufficiently compact or economical to put into a consumer product

### DISCLOSURE OF INVENTION

The instant disclosure describes a novel audio circuit that significantly improves performance in FM transmitters while retaining practical utility in the existing analog FM infrastructure. The circuit can be incorporated into several consumer electronic devices, most notably including: (1) a hybrid digital/analog FM multiplexer/transmitter; and (2) a fully digital FM transmitter for analog infrastructure.

Summarily stated, the inventive circuitry replaces analog multiplexing circuitry by digitizing the raw analog input and using a digital signal processor (DSP) to perform all the filtering, modulating, and mixing involved in producing a multiplex composite signal. In the case of the hybrid design, the composite signal is output from the DSP through a digital/analog converter (DAC), and modulates a conventional FM RF stage. In the case of the fully digital design, the carrier modulation takes place in the DSP, and FM modulated RF is output via a fast DAC for final filtering and radiation.

The novel features characteristic of the invention, as to organization and method of operation, together with further objects and advantages thereof will be understood from the following description considered in connection with the accompanying drawing, in which preferred embodiments of the invention are illustrated by way of example. It is to be expressly understood, however, that the drawing is for illustration and description only and is not intended as a definition of the limits of the invention. The various features of novelty which characterize the invention are pointed out with particularity in the claims annexed to and forming part of this disclosure. The invention resides not in any one of these features taken alone, but rather in the particular combination of all of its structures for the functions specified.

### BRIEF DESCRIPTION OF THE DRAWINGS

The invention will be better understood and objects other than those set forth above will become apparent when consideration is given to the following detailed description thereof Such description makes reference to the annexed drawings wherein:

FIG. 1 is a schematic block diagram showing prior art circuitry for an analog multiplexer;

FIG. 2 is a schematic block diagram showing the RDS subcarrier generation function of the hybrid FM transmitter of the present invention;

FIG. 3 is a schematic block diagram showing the hybrid digital/analog FM transmitter of the present invention; and

FIG. 4 is a schematic block diagram of a second preferred embodiment of the present invention, namely a fully digital transmitter for analog infrastructure.

### BEST MODE FOR CARRYING OUT THE INVENTION

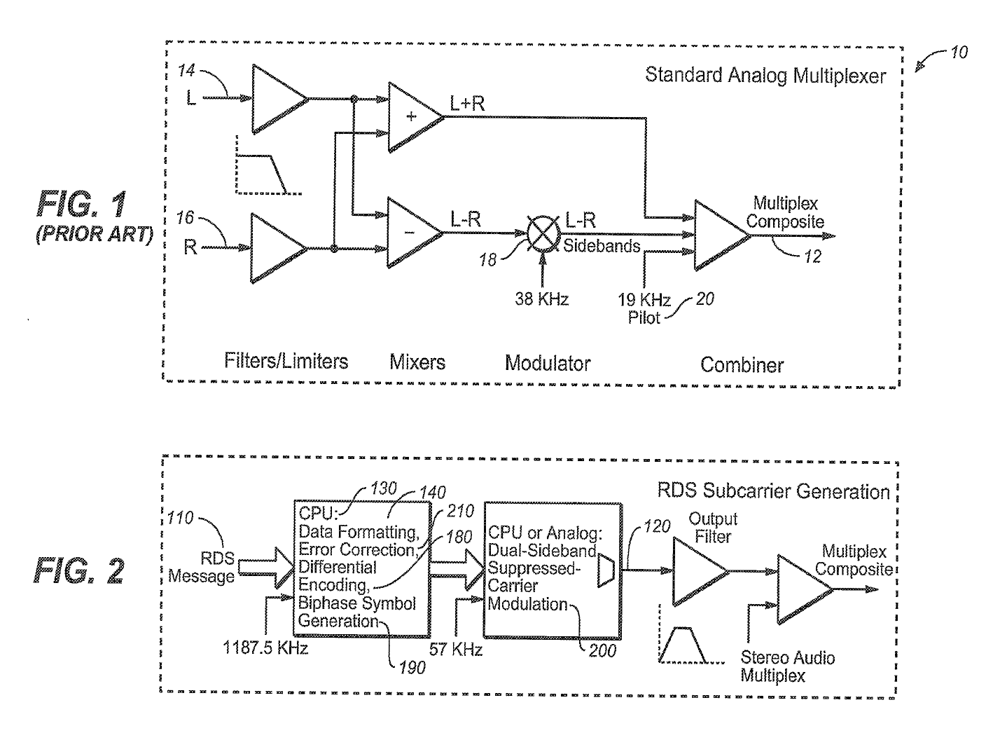

Prior Art Stereo Multiplexer Components: Referring now to FIG. 1, the standard analog FM transmitter 10, well known in the prior art, must generate a stereo “multiplex” composite signal 12 of L+R mono baseband audio signals 14/16, plus L−R sidebands modulated 18 around 38 KHz with a 19 KHz pilot tone 20 mixed in. This multiplex composite signal is fed into a conventional FM RF modulator. The performance of a purely analog approach is limited by the characteristics of the analog circuitry, notably including limited channel separation due to internal crosstalk, noise injection at every semiconductor stage, and distortion introduced in all amplifiers.

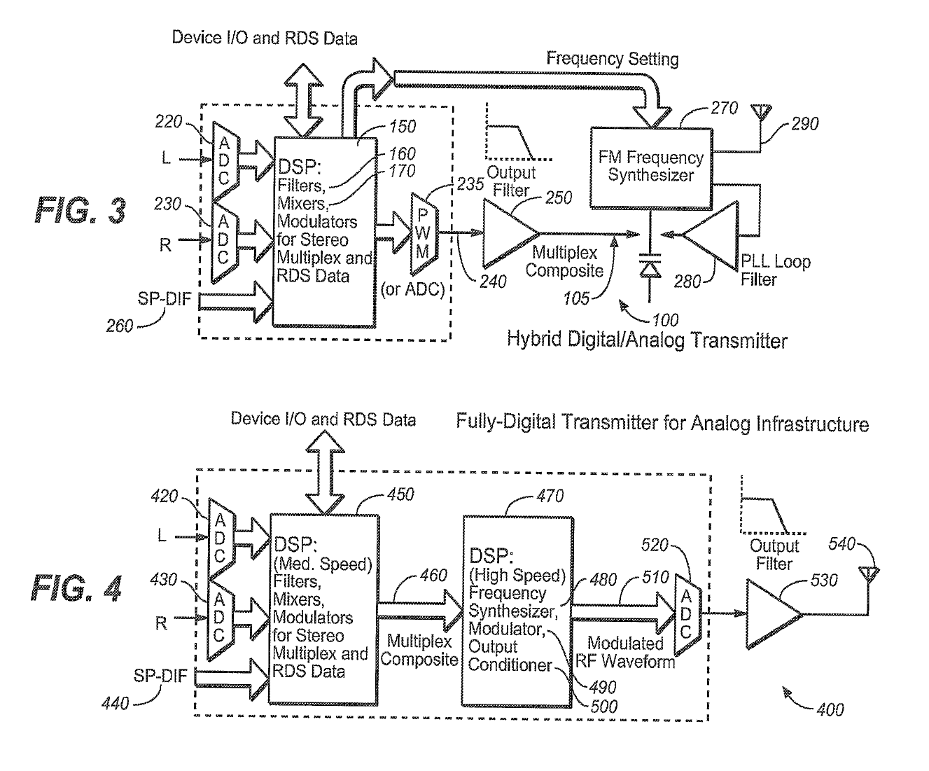

Inventive Hybrid Digital Digital/Analog FM Multiplexer/Transmitter: Referring now to FIGS. 2 and 3, the hybrid digital/analog FM multiplexer/transmitter of the present invention 100 performs all of the analog signal processing in the digital domain with digital signal processing. The result is an analog stereo multiplex composite signal 105 produced with none of the characteristic performance degradation of analog signal processing. The hybrid transmitter comprises stereo multiplexer and RDS modulator components.

Radio Data System (RDS) or Radio Broadcast Data System (RBDS) information 110 (RDS and RBDS are used synonymously and interchangeably herein) is generated on a 57 KHz subcarrier 120 carrying data at 1187.5 bits per second. It can accomplish most of this in a CPU 130 which also effects data formatting 140. However, it must still be filtered and mixed.

The hybrid transmitter digitizes the raw audio, and performs all the signal processing of the standard analog approach in the digital signal processor (DSP) software. The DSP 150, which term as used herein means a computer processor executing digital signal processing code, implemented on a DSP-type processor or any other suitable CPU, can accomplish all the filtering and processing, including:
input filtering and limiting 160, L+R and L−R summing, L−R/38 KHz modulation;
19 KHz pilot mixing 170;
RDS differential encoding 180;
biphase signal generation 190;
DSBSC modulation 200;
notch filtering;
synchronization of the RDS with the 19 KHz pilot in sync or in quadrature; and
correction of non-linearities in the FM RF modulator 210.

The hybrid multiplexer architecture includes dual (first and second) audio-quality ADC's 220/230 on the signal inputs, a medium-speed DSP 150 to perform the filtering and modulating functions, and a third ADC to convert the signal from the DSP. The third ADC can be selected from any of a number of suitable classic electronic ADCs (including, without limitation, direct conversion, successive approximation, delta encoded, ramp compare or multi-slope, pipeline, sigma-delta, and so on). Alternatively, the third ADC can be selected to effect pulse width modulation and to produce a 1-bit pulse-width modulated (PWM) output 240. Some analog filtering 250 on the output is required to reconstruct and condition the multiplex composite signal 105 and limit the harmonics, and the signal is sent to an FM frequency synthesizer 270, which includes a phase-locked loop filter 280, and which sets a stable reference frequency before the output is sent to the transmitting antenna 290. The precise degree and exact type of filtering (e.g., lowpass, bandpass, etc.) at filter 250 is tailored to the type of ADC employed and the types of undesirable harmonics generated therein. Additionally, the RF Output from antenna 290 may be fed into additional circuitry for amplification, attenuation, or filtering, depending on the intended purpose and on the other devices likely to be employed in the communication system.

Alternate options include taking a direct-digital input using a Sony/Philips Digital Interface Format (“SP-DIF” or “S/PDIF”) 260 or some other digital standard (thereby bypassing the input ADCs), and using a real ADC on the output rather than the PWM. The DSP can also serve as the system controller, operating buttons, display, and providing the tuning data to the FM Frequency Synthesizer.

Referring now to FIG. 4, in an alternative embodiment, the present invention can be employed to provide a fully digital FM multiplexer/transmitter for an analog infrastructure.

The digital FM multiplexer of the hybrid transmitter may be extended to the FM frequency synthesizer for an end-to-end fully-digital transmitter 400, but having an analog FM signal output 410. This would appear to be a next logical step in making FM digital without requiring digital FM receivers.

The implementation of such an architecture is relatively simple in theory and concept. As with the first preferred embodiment. ADC's 420/430 are used on the signal inputs (or bypassed if a S/PDIF signal 440 is received), and then fed into a first (medium speed) DSP 450, which performs filtering and modulating functions. A multiplex composite signal output 460 from the first DSP is then fed into a second DSP 470 for high speed frequency synthesizing 480, further modulation 490, and output conditioning 500, including calculating the frequency deviations based on the multiplex composite signal data rather than an analog signal. The modulated RF waveform output 510 would pass through a high-speed ADC 520 of limited but sufficient resolution to be minimally filtered without significant phase noise. Again, some analog filtering 530 on the output may be desired to reconstruct and condition the multiplex composite signal 410 before being sent to a transmitting antenna 540. Further, the filtering at filter 530 is tailored to the ADC used and the undesirable harmonics generated by the ADC, and the signal from transmitting antenna 540 may be subjected to further conditioning with additional circuitry.

Note that the functionality may be combined in one processor or broken up among several as convenient and economical.

The foregoing disclosure is sufficient to enable those with skill in the relevant art to practice the invention without undue experimentation. The disclosure further provides the best mode of practicing the invention now contemplated by the inventor.

While the particular hybrid digital digital/analog FM multiplexer/transmitter apparatus herein shown and disclosed in detail is fully capable of attaining the objects and providing the advantages stated herein, it is to be understood that it is merely illustrative of the presently preferred embodiment of the invention and that no limitations are intended concerning the detail of construction or design shown other than as defined in the appended claims. Accordingly, the proper scope of the present invention should be determined only by the broadest interpretation of the appended claims so as to encompass obvious modifications as well as all relationships equivalent to those illustrated in the drawings and described in the specification.

What is claimed as invention is:

1. A digital/analog FM multiplexer/transmitter for processing an input signal to produce an output analog stereo multiplex composite signal, comprising:
a stereo multiplexer portion, including a DSP; and
an RDS modulator portion.

2. The digital/analog FM multiplexer/transmitter of claim 1, wherein the input signal is a raw analog signal, and wherein said stereo multiplexer portion includes:
a first ADC and a second ADC into which the raw analog signal is input;
a medium-speed DSP for filtering and modulating the signal after conversion by said first and second ADCs;
a third ADC to convert the DSP output signal to an analog signal;
a filter into which said third ADC output is fed and which reconstructs and condition the multiplex composite signal to limit undesired harmonics;
an FM frequency synthesizer; and
a transmitting antenna.

3. The digital/analog FM multiplexer/transmitter of claim 2, wherein said filter is selected according to the type of said third ADC employed and the specific kinds of undesirable harmonics generated by said third ADC.

4. The digital/analog FM multiplexer/transmitter of claim 2, further including an auxiliary circuit to condition the RF output from said transmitting antenna.

5. The digital/analog FM multiplexer/transmitter of claim 4, wherein said auxiliary circuit includes circuitry to amplify, attenuate, and/or filter the output from said transmitting antenna.

6. The digital/analog FM multiplexer/transmitter of claim 2, wherein said DSP is implemented on a DSP-type processor and includes DSP software that executes signal filtering and processing functions selected from the group consisting of: input filtering and limiting; L+R and L−R summing; L−R/38 KHz modulation; 19 KHz pilot mixing; RDS differential encoding; biphase signal generation; DSBSC modulation; notch filtering; synchronization of the RDS with the 19 KHz pilot in sync or in quadrature; correction of non-linearities in a FM RF modulator; and any combination or sub-combination thereof.

7. The digital/analog FM multiplexer/transmitter of claim 2, wherein said FM frequency synthesizer includes a phase-locked loop filter for setting a stable reference frequency before the frequency synthesizer output is sent to said transmitting antenna.

8. The digital/analog FM multiplexer/transmitter of claim 2, wherein said third ADC is selected from the group consisting of direct conversion, successive approximation, delta encoded, ramp compare, multi-slope, pipeline, and sigma-delta.

9. The digital/analog FM multiplexer/transmitter of claim 2, wherein said third ADC produces a 1-bit PWM output signal.

10. The digital/analog FM multiplexer/transmitter of claim 2, wherein said RDS signal modulator portion is implemented in a CPU.

11. The digital/analog FM multiplexer/transmitter of claim 1, wherein said stereo multiplexer portion includes:
first and second ADCs for converting raw analog input signals;
a first DSP for filtering and modulating the signal after conversion by said first and second ADCs, for directly receiving input signals in a digital format which bypass said first and second ADCs, and for producing a multiplex composite signal;
an FM frequency synthesizer; and
a transmitting antenna.

12. The digital/analog FM multiplexer/transmitter of claim 11, further including:
a third ADC to convert the signal output from said first DSP to an analog signal; and
a filter into which a multiplex composite signal output from said third ADC is fed and which reconstructs and conditions the multiplex composite signal to limit undesired harmonics before sending the signal to said FM frequency synthesizer.

13. The digital/analog FM multiplexer/transmitter of claim 11 further including a second DSP into which the multiplex composite signal is fed for high speed frequency synthesizing, further modulation and signal conditioning, and output of a modulated RF waveform.

14. The digital/analog FM multiplexer/transmitter of claim 13, wherein said second DSP calculates frequency deviations based on the multiplex composite signal data.

15. The digital/analog FM multiplexer/transmitter of claim 13, further including a final ADC through which the modulated RF waveform from said second DSP.

16. The digital/analog FM multiplexer/transmitter of claim 15, further including a filter into which the output of said final ADC for reconstructing and condition the multiplex composite signal before sending the signal to said transmitting antenna.

17. A method of producing a multiplex composite signal from a raw analog input signal, comprising the steps of feeding the raw analog input signal into a circuit which digitizes the raw analog input by using a digital signal processor (DSP) having digital signal processing software for filtering, modulating, and mixing the raw analog input and outputting the multiplex composite signal which includes a modulated RF waveform.

18. The method of claim 17, further including the step of filtering and radiating the modulated RF waveform by using a digital/analog converter (DAC).
